(19) United States
(12) Patent Application Publication
(10) Pub. No.: US 2026/0044119 A1
(43) Pub. Date: Feb. 12, 2026

(54) ADAPTIVE RINGING CANCELLATION IN CAN RECEIVERS

(71) Applicant: Infineon Technologies AG, Neubiberg (DE)

(72) Inventors: Andrea GALLONE, Unterhaching (DE); Eric PIHET, München (DE)

(21) Appl. No.: 19/292,087

(22) Filed: Aug. 6, 2025

(30) Foreign Application Priority Data
Aug. 9, 2024 (DE) 102024122856.3

(51) Int. Cl. G04F 10/00; H03L 7/085; H04L 12/40

(52) U.S. Cl. CPC G04F 10/005; H03L 7/085; H04L 12/40; H03L 2207/50; H04L 2012/40215

(57) ABSTRACT

A circuit comprises a CAN bus line with two wires, an adaptive notch filter that is coupled to the CAN bus line and configured to filter a CAN signal received from the CAN bus line, and a CAN receiver. The circuit further comprises a first comparator circuit, a time-to-digital converter, and a digital control circuit. The first comparator circuit is coupled to the CAN bus line and configured to generate an output signal representing a ringing of the CAN signal. The time-to-digital converter is coupled to the first comparator circuit and configured to convert the output signal of the first comparator circuit into a digital word representing a frequency of the ringing. The digital control circuit is connected to the time-to-digital converter and configured to digitally control a frequency response of an adaptive notch filter based on the digital word.

### TECHNICAL FIELD

This application relates to the field of CAN bus communications, in particular to the suppression of the CAN ringing in the CAN signal.

### BACKGROUND

Controller Area Network, CAN, buses are widely used buses for communication between Electrical Control Units (ECUs) in the automotive field, in particular in wiring harnesses in automobiles. CAN buses are known to be particularly robust and reliable.

There is an increasing demand for improving the CAN protocol to account for the growing connectivity requirements in the automotive field. In particular, increasing the data rate has been one of the main objectives. This is usually achieved by increasing the data frame length as well as the throughput.

In modern CAN systems, due to unterminated stubs in the wiring harness and signal plateaus, created by a lower characteristic cable impedance, signal ringing still limits reliable communication during arbitration phase at frequencies higher than 2.5 MHz.

There are some solutions to reduce the ringing by modifying the network topology and the transmitter. However, these solutions strongly depend on the CAN bus characteristics and need to be adapted to each particular topology, which can be particularly time-and cost-expensive.

### SUMMARY

The above-mentioned may be addressed by the circuit of claim 1, in particular by using a notch filter in front of the receiver and a feedback circuit that is configured to estimate a frequency of the ringing on the CAN lines and to tune a frequency response of the notch filter based on the determined ringing frequency, as well as by the method of claim 15.

In one example, the disclosure is directed to a circuit comprising a CAN bus line with two wires, an adaptive notch filter that is coupled to the CAN bus line and configured to filter a CAN signal received from the CAN bus line, and a CAN receiver. The CAN receiver is configured to receive a filtered CAN signal from the adaptive notch filter and to provide, based on the filtered CAN signal, an output signal for a microcontroller. The circuit further comprises a first comparator circuit, a time-to-digital converter, and a digital control circuit. The first comparator circuit is coupled to the CAN bus line and configured to generate an output signal representing a ringing of the CAN signal. The time-to-digital converter coupled to the first comparator circuit and configured to convert the output signal of the first comparator circuit into a digital word representing a frequency of the ringing. The digital control circuit is connected to the time-to-digital converter and configured to digitally control a frequency response of the adaptive notch filter based on the digital word.

In one example, the disclosure is directed to a method comprising the steps of: filtering, by an adaptive notch filter, a CAN signal received from a CAN bus line; receiving, by a CAN receiver, a filtered CAN signal from the adaptive notch filter and providing, based on the filtered CAN signal, an output signal for a microcontroller; generating, by a first comparator circuit, an output signal representing a ringing of the CAN signal; converting, by a time-to-digital converter, the output signal of the first comparator circuit into a digital word representing a period frequency of the ringing; and digitally controlling, by a digital control circuit, a frequency response of the adaptive notch filter based on the digital word.

### BRIEF DESCRIPTION OF THE DRAWINGS

The embodiments described herein can be better understood with reference to the following description and drawings. The components in the figures are not necessarily to scale, emphasis instead being placed upon illustrating the principles of the embodiments. Furthermore, in the figures, like reference numerals designate corresponding parts. In the drawings:

FIG. 1 illustrates a first example of a circuit for removing the ringing from a CAN signal in accordance with one or more techniques described herein.

FIG. 2 illustrates the circuit of FIG. 1 in more detail.

FIG. 3 illustrates an example of a circuit structure of a notch filter that can be used in the example circuit of FIGS. 1 and 2.

FIG. 4 illustrates (a) a diagram showing the amplitude of a typical ringing on a CAN bus line depending on the frequency, (b) a typical transfer function of a notch filter depending on the frequency, and (c) a typical transfer function of a low-pass filter depending on the frequency.

FIG. 5 illustrates another example of a circuit for removing the ringing from a CAN signal in accordance with one or more techniques described herein.

FIG. 6 illustrates the circuit of FIG. 5 in more detail.

FIG. 7 illustrates a time diagram showing the output signals of various components of the circuit of FIG. 6.

FIG. 8 illustrates a portion of the RX signal output by the CAN receiver of FIG. 5 (a) before adjustment of the sampling point and (b) after adjustment of the sampling point.

FIG. 9 is a flowchart illustrating an example method for removing the ringing from a CAN signal, in accordance with one or more techniques described in this disclosure.

### DETAILED DESCRIPTION

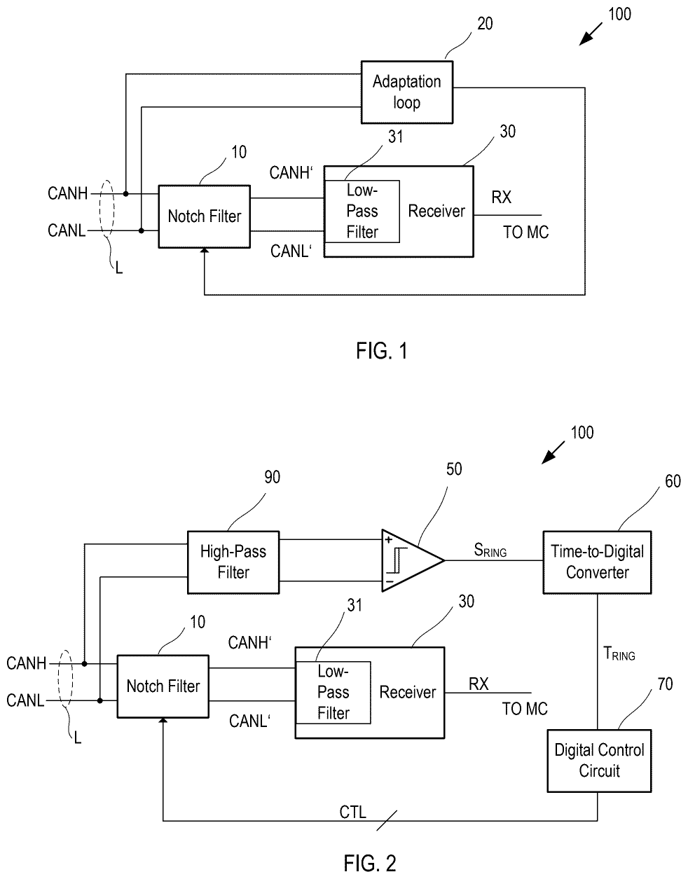

FIG. 1 shows an example of a circuit 100 for suppressing/attenuating the ringing from a CAN signal. The circuit comprises a CAN bus line L having two parallel wires along which the wire signals CANH and CANL are transmitted. The CAN signal is the differential signal between the wire signals CANH and CANL and has a typical square-wave form for transmitting bit information. That is, the CAN signal is the difference between the signal levels of CANH and CANL, while the average signal level of CANH and CANL is referred to as common mode voltage. The CAN bus line is coupled to a CAN receiver 30 that provides an output signal RX for a microcontroller MC (not shown in FIG. 1) based on the received CAN signal. The CAN receiver 30 is connected to a corresponding CAN transmitter (not shown). In one example, the CAN receiver 30 comprises a low-pass filter 31 that is configured to filter out undesired high-frequency components that may be included in the CAN signal.

CAN bus lines are known to be very robust communication systems. However, CAN bus lines are prone to ringing, which is mostly due to reflections caused by imperfect termination impedances in the CAN bus nodes. Ringing is a sinusoidal, attenuating signal having a main frequency, the so-called ringing frequency. An example of the amplitude A(f) of a ringing signal component depending on the frequency f is illustrated in FIG. 4(a). The ringing has a relatively narrow spectrum which has a central ringing frequency fᵣ at which the amplitude of the ringing is maximum and slightly extends around the ringing frequency fᵣ. The ringing frequency fᵣ is strongly dependent on the used system and is usually in the range of 10 to 40 MHz for a CAN signal speed of 2 Mbit/s. Ringing usually happens after a falling edge of the square-wave differential CAN signal though it may also occur at a rising edge of the differential CAN signal.

In order to attenuate (ideally remove) the ringing, the circuit further comprises a filter 10 that is coupled to the CAN bus line L and configured to filter the CAN signal received from the CAN bus line. The filter 10 is arranged in front of the receiver 30, so that the receiver 30 receives the filtered CAN signal CANH′, CANL′ from the filter 10.

According to one example, the filter is a notch filter 10, also called stop band filter. Notch filters are highly selective, high quality factor (high Q) filters that are able to reject a very narrow frequency band. They are basically composed of a combination of a low pass filter and a high pass filter. FIG. 4(b) shows a typical frequency response F(f) of a notch filter. The notch filter lets pass all frequencies, except in the frequency band Δf that is centered around the notch frequency fₙ, which is the frequency of maximum attenuation. The lower and upper frequencies f₁ and f₂ at which the attenuation is equal to 3 dB are called cut-off frequencies. The blocking frequency bandwidth Δf between the cut-off frequencies is very narrow. The quality factor Q describes the selectivity of the notch filter and can be defined as the ratio between the notch frequency and the bandwidth between the frequencies for which the attenuation is equal to half the maximum attenuation at the notch frequency fₙ. The higher the quality factor, the narrower the bandwidth Δf of the blocking frequency band.

The notch filter 10 is configured to filter the ringing and outputs filtered a CAN signal CANH′, CANL′ to the receiver 30 (and, thus, the low-pass filter 31). According to one example, the notch filter 10 is adaptable, i.e. the notch frequency fₙ (and optionally also the quality factor Q) of the notch filter 10 can be tuned. For this purpose, the circuit also comprises an adaptation loop 20 that is coupled to the CAN bus line L and that is configured to determine the ringing frequency fᵣ on the CAN bus line L. The adaptation loop 20 is connected to the notch filter 10 and is further configured to tune the frequency response of the notch filter 10 depending on the determined ringing frequency fᵣ. In one example, the adaptation loop 20 is configured to tune at least one of the following filter parameters of the notch filter 10: the notch frequency fₙ, the quality factor Q, the cut-off frequencies f₁ and f₂, and the blocking frequency bandwidth Δf. With this, the notch filter 10 is able to remove the ringing frequency fᵣ, so that the receiver 30 receives filtered signals CANH′, CANL′ having less or no ringing. The adaptation of the notch filter 10 may be carried out in one step or in multiple iterations. The adaptation loop 20 is thus a feedback circuit that enables the notch filter 10 to selectively remove the determined ringing frequency fᵣ.

FIG. 2 illustrates a more detailed example of the circuit of FIG. 1. In the example of FIG. 2, the notch filter 10 is designed in such a way that the frequency response of the notch filter 10 can be digitally controlled. For this purpose, the adaptation loop 20 comprises a first comparator circuit 50 that is coupled to the CAN bus line L, a time-to-digital converter 60 (TDC) that is coupled to the first comparator circuit 50, and a digital control circuit 70 that is connected to the time-to-digital converter 60. In one example, the adaptation loop 20 further comprises a high-pass filter 90 that is arranged in front of the first comparator circuit 50 (i.e. between the CAN bus lines L and the inputs of the comparator circuit 50).

The high-pass filter 90 receives the (differential) CAN signal CANH, CANL and is configured to filter out possible DC components as well as lower frequencies of the useful CAN signal, and to let pass the higher frequencies that contain the ringing frequency. Ideally, the filtered signals output by the high-pass filter 90 only contain the ringing component of the CAN signal, and the first comparator circuit 50 essentially receives the ringing.

The first comparator circuit 50 receives the filtered CAN signal output by the high-pass filter 90 and is configured to generate an output signal S_{RING} representing the ringing of the CAN signal. In one example, the first comparator circuit 50 is a comparator with a small hysteresis and a threshold at 0 V, and the output signal S_{RING} is basically a square-wave signal, wherein a low value corresponds to a positive section of the received signal and a high value corresponds to a negative section of the received signal. A width of a high value part of the output signal S_{RING} thus corresponds to a half-period of the ringing.

The time-to-digital converter 60 receives the output signal S_{RING} from the first comparator circuit 50 and is configured to convert the output signal S_{RING} into a digital word T_{RING} (a bit string) representing a frequency of the ringing. For this purpose, the TDC is configured to sample the square-wave signal S_{RING}. In one example, the time-to-digital converter 60 has a high resolution. According to one embodiment, the resolution of the TDC is less than 200 ps. According to another embodiment, the TDC resolution is less than 100 ps. For example, the TDC may be a ring-oscillator-based time-to-digital converter that uses a ring oscillator structure. By using a high resolution TDC, it is possible to make sure that the square-wave signal S_{RING} can be properly sampled and, in particular, to precisely determine the ringing frequency fᵣ based on the square-wave signal S_{RING}. In particular, assuming a ringing frequency fᵣ of 40 MHz over a CAN signal with a speed of 2 Mbit/s, a sampling frequency of at least 80 MHz would be required for the TDC. With a TDC having a resolution of 100 ps, a sampling frequency of 10 GHz can be achieved, which can provide a very precise sampling of the square-wave signal S_{RING} and a precise determination of the ringing frequency fᵣ (or of the ringing period).

The digital control circuit 70 receives the digital word T_{RING} from the time-to-digital converter 60 and is configured to output a digital control signal CTL (which may also be a digital word, i.e. a group of bits) for digitally controlling the frequency response of the adaptive notch filter 10 based on the digital word T_{RING}. Because of the high resolution of the TDC, the frequency response of the notch filter 10, in particular the notch frequency and the quality factor, can be very precisely tuned by the digital control circuit 70. As a result, there is a higher freedom on the choice of the design for the notch filter 10. As an example, the notch filter 10 can be a filter with a very simple design, such as a second-order filter.

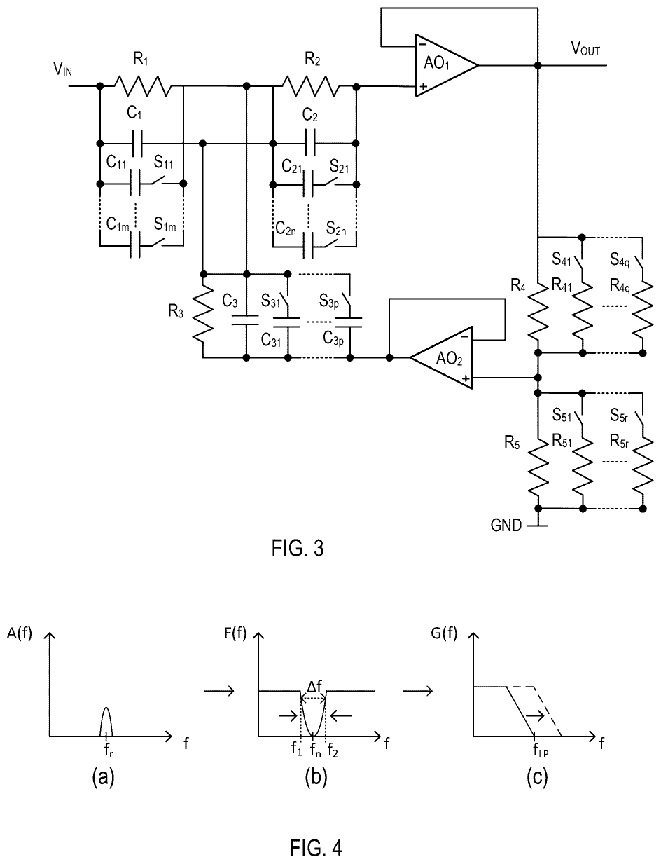

FIG. 3 shows an example of a circuit structure for the adaptive notch filter 10 of FIGS. 1 and 2. The circuit is a second-order filter that comprises two RC branches in the form of two tee sections connected in parallel and a voltage resistive divider that is connected through two operational amplifiers AO₁ and AO₂ in feedback to the RC network. The first tee section comprises two resistors R₁ and R₂ arranged in series, as well as a first array of capacitors C₃ and C₃₁-C₃ₚ, n being an integer, wherein n>1. The capacitors C₃, C31-C₃ₚ are arranged in parallel and are connected to both resistors R₁ and R₂ at a node between the resistors R₁, R₂. The second tee section comprises a second array of capacitors C₁, C11-C₁ₘ and a third array of capacitors C₂, C₂₁-C₂ₙ that are arranged in series, as well a third resistor R₃ connected to both capacitors C₁ and C₂ at a node between the capacitors C₁, C₂. Each of the capacitors C₁₁-C₁ₘ, C₂₁-C₂ₙ, C₃₁-C₃ₚ is connected in series with a corresponding switch S₁₁-S₁ₘ, S₂₁-S₂ₙ, S₃₁-S₃ₚ and can be selectively switchable by the corresponding switch. In one example, the switches S₁₁-S₁ₘ, S₂₁-S₂ₙ, S₃₁-S₃ₚ are configured to be switched on and off depending on the digital control signal CTL generated by the digital control circuit 70 based on the digital word T_{RING} representing the ringing frequency. The capacities of the three capacitor arrays can thus be digitally tuned by the digital control circuit 70. Since the notch frequency fₙ of the notch filter 10 depends on the capacities of the capacitor arrays, it is possible to adjust the notch frequency fₙ in a very precise and simple manner such that the ringing frequency fᵣ is effectively removed by the notch filter 10. In one example, the notch filter 10 is tuned so that the notch frequency fₙ is (substantially) equal to the ringing frequency fᵣ.

Further, the voltage resistive divider comprises a first array of resistors R₄, R₄₁-R_{4q} and a second array of resistors R₅, R₅₁-R₅ᵣ that are arranged in series. Each of the resistors R₄₁-R_{4q} and R₅₁-R₅ᵣ is connected in series with a corresponding switch S₄₁-S_{4q}, S₅₁-S₅ᵣ and can be selectively switchable by the corresponding switch. In one example, the switches S₄₁-S_{4q}, S₅₁-S₅ᵣ are configured to be switched on and off depending on the digital control signal CTL generated by the digital control circuit 70 based on the digital word T_{RING} representing the ringing frequency. The resistances of the two resistor arrays can thus be digitally tuned by the digital control circuit 70. Since the quality factor Q of the notch filter 10 depends on the ratio between the resistance of the second resistor array R₅, R₅₁-R₅ᵣ and the total resistance of the first and second resistor arrays, it is possible to adjust the quality factor Q, and, thus, the cut-off frequencies f₁, f₂ and the stop frequency bandwidth Δf, in a very precise and simple manner such that the selectivity of the notch filter 10 can be increased or decreased.

In one example, the notch filter 10 is tuned such that the bandwidth of the stop frequency band Δf is large (low quality factor Q). With this, frequencies of the ringing that are around the ringing frequency fᵣ can also be efficiently removed. In fact, as shown in FIG. 4(a), the ringing is usually not centered on a single frequency, but may spread around the main ringing frequency fᵣ.

According to one embodiment, a delay of the adaptation loop 20 is less than 100 ns. In one embodiment, it is less than 80 ns. In another embodiment, it is less than 60 ns. In one example, assuming a ringing frequency fᵣ of 40 MHz (and, thus, a ringing period of 25 ns), the delay of the high-pass filter 90 and the first comparator circuit 50 is 10 ns, the delay of the TDC is 25 ns, the delay of the digital control circuit 70 is 10 ns and the communication delay between the digital control circuit 70 and the notch filter 10 is 10 ns. This amounts to a total loop delay of 55 ns. It is thus possible to adapt the frequency response of the adaptive notch filter 10 within one period of the ringing.

According to one embodiment, the frequency response of the notch filter 10 is adjusted in various iterations. For example, at each iteration, the digital control signal CTL may be modified and the notch frequency and the quality factor may be adjusted more accurately. When the first comparator circuit 50 does not detect any a ringing and the square-wave output signal S_{RING} of the first comparator circuit 50 remains at a low level, then the notch frequency fₙ of the notch filter 10 remains unchanged. In this case, the digital control circuit 70 does not output a modified digital control signal CTL but keeps outputting the last digital control signal CTL. The notch filter 10 thus also keeps the last configuration.

As mentioned above, the low-pass filter 31 of the CAN receiver 30 is configured to filter the high-frequency components of the CAN signal CANH′, CANL′ output by the notch filter 10. In one example, a parameter of the low-pass filter 31 is adjustable, for example by the receiver 30 itself or by the microcontroller. The parameter may be a cut-off frequency f_{LP} or a frequency bandwidth of the low-pass filter 31. As the notch filter 10 is adjusted to attenuate or, ideally, remove the ringing, the cut-off frequency f_{LP} of the low-pass filter 31 may be adjusted based on the frequency response of the adaptive notch filter 10. In particular, the cut-off frequency f_{LP} of the low-pass filter 31 may be shifted towards higher frequencies. This makes it possible to use a larger frequency bandwidth for the CAN signal.

The circuit of FIG. 2 can be combined with any CAN network topology and can remove the ringing efficiently and independently from the CAN bus characteristics.

FIG. 4 illustrates the adjustments of the parameters of the notch filter 10 and of the low-pass filter 31 of the CAN receiver 30. FIG. 4(a) shows the magnitude A(f) of a typical ringing on a CAN bus line depending on the frequency (i.e. the spectrum). The ringing is centered on a main ringing frequency fᵣ, but slightly extends around this main ringing frequency fᵣ. FIG. 4(b) shows the transfer function F(f) of the notch filter 10 depending on the frequency. The notch filter 10 is configured to attenuate the response around the notch frequency fₙ, wherein the notch frequency fₙ is the frequency of maximum attenuation. The attenuation mostly takes place in the stop frequency band (having a bandwidth Δf) that extends between the cut-off frequencies f₁ and f₂, wherein the attenuation at the cut-off frequencies f₁ and f₂ is equal to 3 dB. The digital control circuit 70 is configured to adjust both the notch frequency fₙ and the quality factor Q (and, thus, also the stop frequency bandwidth Δf and the position of the cut-off frequencies f₁ and f₂). In particular, the digital control circuit 70 may send a control signal CTL that leads to a shift the notch frequency fₙ to the lower or to the higher frequencies, and that either broadens or narrows the frequency bandwidth Δf depending on the determined ringing frequency fᵣ. As already mentioned, this adjustment process may be carried out in various iterations. FIG. 4(c) shows the transfer function G(f) of the low-pass filter 31 of the receiver 30. The low-pass filter 31 receives the CAN signal CANH′, CANL′ filtered by the notch filter 10 and is configured to cut off frequencies above the cut-off frequency f_{LP}. As the frequency response of the notch filter 10 is adapted and the ringing is attenuated, the cut-off frequency f_{LP} of the low-pass filter 31 may be shifted to higher frequencies. In one example, the cut-off frequency f_{LP} of the low-pass filter 31 is shifted depending on the notch frequency fₙ. In multiple iterations, the bandwidth of the low-pass filter 31 can thus be progressively increased and the notch frequency and quality factor Q of the notch filter 10 may be more accurately adjusted.

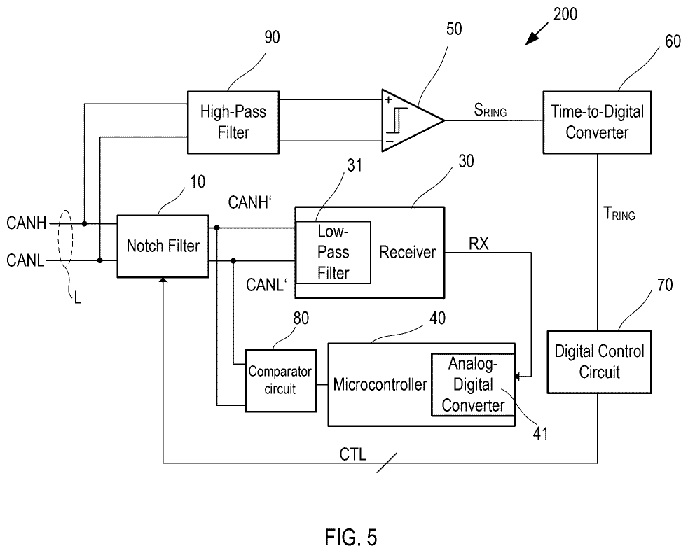

FIG. 5 shows another example of a circuit 200 for removing the ringing from a CAN signal. FIG. 5 shows the microcontroller 40, which is also part of the circuit 200. The microcontroller is also part of the circuit 100 of FIGS. 1 and 2, but is not shown in these figures for clarity reasons. The microcontroller 40 is connected to the CAN receiver 30 and is configured to sample the output signal RX of the CAN receiver 30. The output signal RX corresponds to the differential CAN signal after filtering by the notch filter 10 and by the low-pass filter 31 of the CAN receiver 30. It has a square-wave form. The microcontroller 40 comprises an analog-digital converter, ADC, 41 that is configured to sample the signal RX and encode it into a binary code.

Compared with the circuit 100 of FIG. 2, the circuit 200 further comprises a second comparator circuit 80 that is connected to the CAN bus line L after the notch filter 10 and, thus, receives, as inputs, the filtered CAN signal CANH′, CANL′. The second comparator circuit 80 is connected to the microcontroller 40 and is configured to evaluate the function of the notch filter 10, more especially to check whether the adaptation has reached a target cancellation of the ringing. The second comparator circuit 80 is configured to determine whether an amplitude of the ringing is below a predetermined threshold. The second comparator 80 then sends the information to the microcontroller 40, which can evaluate whether to extend a sampling window of the analog digital converter 41, as described below.

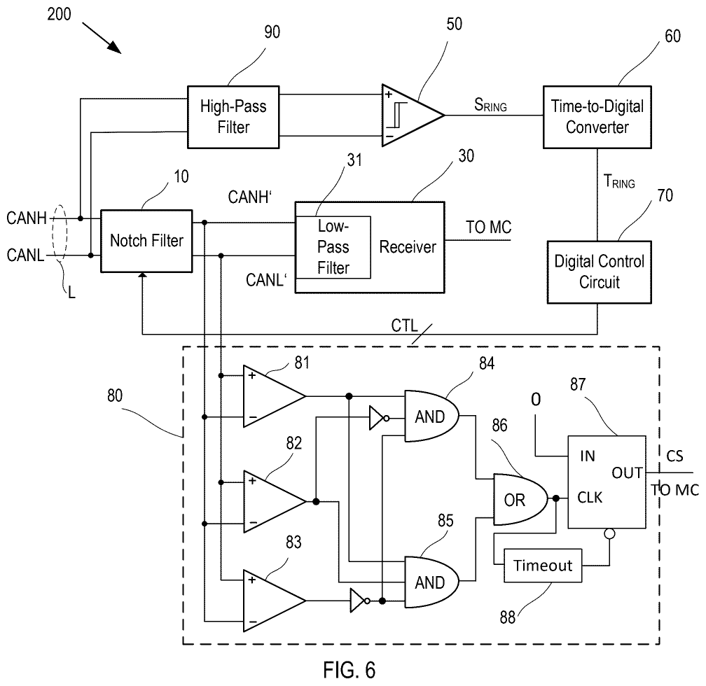

FIG. 6 illustrates a more detailed example of the circuit of FIG. 5. According to one embodiment, the second comparator circuit 80 comprises a plurality of comparators 81, 82, 83 that are each configured to determine whether the ringing is below a respective threshold, as well as a logic circuit that is configured to output a signal to the microcontroller 40 indicating whether the ringing is within an acceptable range. In the example of FIG. 6 the second comparator circuit 80 comprises three comparators 81, 82, 83. The comparators 81, 82, 83 are each configured to receive the CAN signal CANH′, CANL′ filtered by the notch filter 10 and to output a high value (“1”) when the amplitude of the ringing is below a first, a second and a third predetermined threshold, respectively. The comparators 81, 82, 83 are also configured to remove any DC components of the CAN signals. Practically, this means that the comparators 81, 82, 83 consider the amplitude of the differential CAN signal when it has a low level (corresponding to a logical “0”) and compare it to the relevant threshold. In one example, the first threshold is 0.5V, the second threshold is 0.7V and the third threshold is 0.9V, wherein the differential CAN signal has a low value that is lower than 0.5V and a high value that is higher than 0.9V.

The logic circuit of the second comparator circuit 80 is configured to output a signal CS to the microcontroller that indicates whether the amplitude of the ringing is below the second or below the third threshold. In the example of FIG. 6, the logic circuit comprises two AND gates 84, 85, an OR gate 86 and a flip-flop circuit 87. The AND gates 84 and 85 are connected to the outputs of the comparators 81, 82, 83, wherein the first AND gate 84 is configured to output a high value when the amplitude of the ringing is above the first threshold but below the second and the third threshold and the second AND gate 85 is configured to output a high value when the amplitude of the ringing is above the first threshold and the second threshold but below the third threshold. The OR gate 86 is connected to the outputs of the AND gates 84 and 85 and outputs a high value when either the first or the second AND gate 84, 85 outputs a high value, namely when the comparators 81, 82, 83 output signals with different values (the values being either low or high). When there is no ringing, the comparators 81, 82, 83 are configured to output the same value. When the comparators 81, 82, 83 output different values, this means that a glitch or ringing is detected. Therefore, the OR gate 86 is configured to only output a high value in case of a glitch or a ringing. By using different comparators having different thresholds, the detection of these ringing events can be more precise. The output of the OR gate 86 is connected to the flip-flop circuit 87 which is configured to output a signal CS with a high value to the microcontroller 40 when a falling edge of the output signal of the OR gate 86 is detected, namely when the comparators 81, 82, 83 output signals having the same value (high or low) after outputting signals having different values. This corresponds to an end of a ringing event.

Further, the output of the OR gate 86 may also be connected to a timeout circuit 88. An output of the timeout circuit 80 is connected to the flip-flop circuit 87. The timeout circuit 80 is triggered by a falling edge of the output signal of the OR gate 86. If, during a predetermined timeout period, no rising edge of the output signal of the OR gate 86 is detected, the timeout circuit 80 is configured to output a timeout value. Upon receiving the timeout value, the flip-flop circuit 87 is configured to output a signal CS with a low value, i.e. the flip-flop is reset. The flip-flop circuit may be replaced by a corresponding latch and the logic circuit may be replaced by an equivalent circuit. In one example, based on the value of the CS signal output by the second comparator circuit 80, the microcontroller 40 can adjust, for each received bit of the output signal RX, a sampling window, as illustrated in FIG. 8. In particular, the microcontroller 40 can adjust, for each received bit, the sampling window when an amplitude of the ringing is less than a predetermined threshold of the second comparator circuit 80.

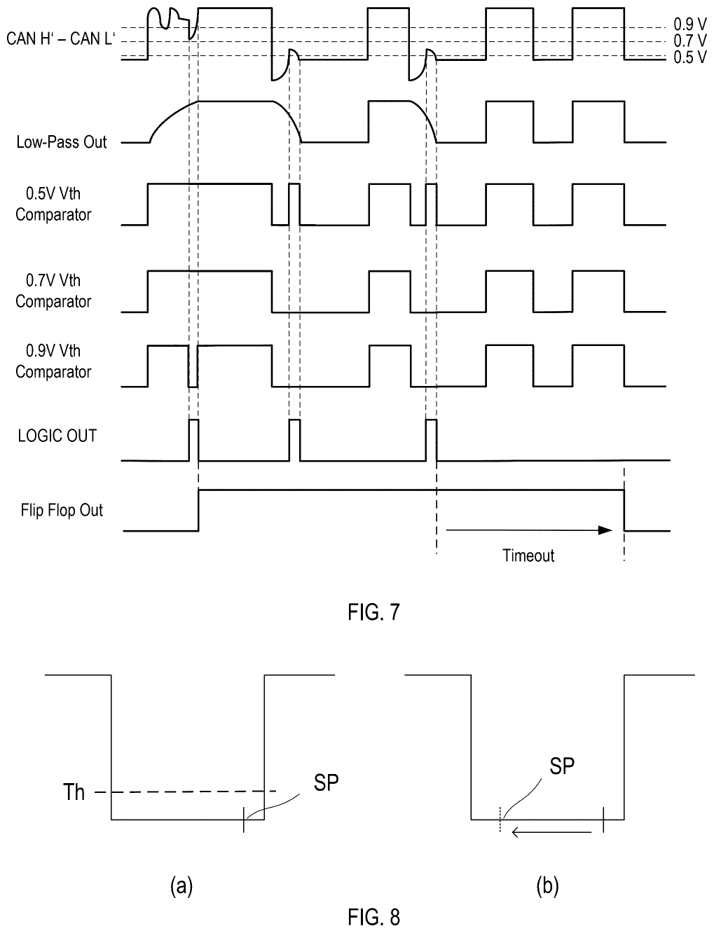

FIG. 7 shows time diagrams of the output signals of the differential CAN signal CANH′-CANL′ after filtering of the CAN signal by the notch filter 10, the low-pass filter 31 of the CAN receiver 30, the comparators 81, 82 and 83, the logic gate 86 and the flip-flop circuit 87. In the depicted example, the comparators 81, 82, 83 are configured to detect thresholds of 0.5V, 0.7V and 0.9V, respectively, wherein the differential CAN signal CANH′-CANL′ is a square-wave signal with a low value that is lower than 0.5V and a high value that is higher than 0.9V. It is assumed that the amplitude of the ringing is less than a difference voltage between a high value and low value of the CAN signal, in particular lower than a difference between the lowest and the highest threshold of the comparators 81, 82, 83, presently 0.4V.

The first time diagram of FIG. 7 shows that the differential CAN signal CANH′-CANL′ experiences several glitches after a rising or a falling edge of the CAN signal, which correspond to ringing events. The following edges of the CAN signal are no longer prone to ringing, which can be interpreted as a sign that the adaptation of the notch filter 10 has worked. The second time diagram shows that the output of the low-pass filter 31 has unclear edges when there is ringing. This prevents a precise sampling of the CAN signal by the microcontroller 40. Because of this, in one example, at the beginning of the adaptation, a sampling point of the microcontroller is arranged at the end of a bit period of the CAN signal in order to reduce the influence of a possible ringing.

The following four time diagrams show the output signals of the comparators 81, 82 and 83, and the output signal of the OR gate 86. When there is no ringing, if the CAN signal has a low value (under 0.5V), none of the comparators is triggered, and, if the CAN signal has a high value (over 0.9V), all the comparators are triggered. Since the comparators all output the same value (all high or all low), the OR gate 86 outputs a low value. During the first glitch after the first rising edge of the CAN signal, the high value of the CAN signal falls under 0.9V due to the ringing, but remains above 0.7V. The third comparator 83 with a threshold of 0.9V outputs a low value, while the other comparators 81 and 82 both output a high value. Since the comparators output different values, the OR gate 86 outputs a high value. During the second glitch after the first falling edge of the CAN signal, the low value of the CAN signal rises above 0.5V due to the ringing, but remains under 0.7V. The first comparator 81 with a threshold of 0.5V outputs a high value, while the other comparators 82 and 83 both output a low value. Since the comparators output different values, the OR gate 86 again outputs a high value. The same happens again for the third glitch after the second falling edge of the CAN signal.

The last time diagram shows the output signal of the flip-flop circuit 87. In the depicted example, the signal of the flip-flop circuit 87 has a low value at the beginning.

After detection of the first falling edge of the output of the OR gate 86, the flip-flop circuit 87 outputs a high value. This corresponds to the transition from a situation in which the outputs of the comparators have different value (ringing) to a situation in which the outputs of the comparators have the same value. However, the return to the “normal” situation in which the outputs of the comparators have the same value does not necessarily means that the ringing is over. For this reason, the timeout circuit 88, which is connected to the flip-flop circuit 87, introduces a timeout period that is triggered by a falling edge of the output of the OR gate 86. The timeout circuit 88 is configured to reset the output of the flip-flop circuit 87 to a low value only if, during the timeout period triggered by a falling edge of the output of the OR gate 86, the output of the OR gate 86 remains low, namely if no ringing is detected. Since the second ringing event is detected before the end of the timeout period, the output of the flip-flop circuit 87 remains at a high value. The second falling edge of the output of the OR gate 86 again triggers a timeout period. However, during this timeout period, the third ringing event is detected and the output of the flip-flop circuit 87 remains at a high value. The third falling edge of the output of the OR gate 86 triggers another timeout period. This time, no ringing is detected during the timeout period (the comparators 81, 82, 83 output the same value and the OR gate 86 outputs a low value), so that the output of the flip-flop circuit 87 is reset to the low value. This generally means that the adaptation of the notch filter 10 was successful or that there is almost no ringing in this part of the CAN signal. The latter may be the case if the CAN signal has a constant value during a time period that exceeds the timeout period.

FIG. 8 illustrates the behavior of the microcontroller 40 depending on the output of the flip-flop circuit 87. FIG. 8(a) shows a portion of the square-wave output signal RX output by the CAN receiver 30. As mentioned above, the ringing (not represented in the figure) typically occurs subsequent to a falling edge of the differential CAN signal, though it may also occur subsequent to a rising edge of the differential CAN signal. The ringing has an attenuating sinus-wave form. In order to ensure that the ringing does not affect the sampling of the output signal RX, the microcontroller 40 samples, for each bit, the output signal RX at a sampling point SP located at an end of a bit period of the signal. In one example, the sampling point SP is arranged at 90% of the bit period before the beginning of the adaptation. With the circuit of FIG. 6, the ringing can be iteratively attenuated until it is within an acceptable range, as illustrated in FIG. 7. According to one embodiment, when the microcontroller 40 determines, based on the output of the second comparator circuit 80, that the ringing is below a predetermined threshold Th, it can adjust the sampling point SP by shifting it towards the beginning of the bit period, as shown in FIG. 8(b). If no ringing is detected, a reliable sampling of the output signal RX of the CAN receiver 30 is possible at the beginning of the bit period because the edges of the output signal RX are sharp, as seen in the second time diagram of FIG. 7. Referring to the example of FIG. 7, when the output of the flip-flop circuit 87 exhibits a falling edge, the microcontroller 40 determines that, during a timeout period, the comparators 81, 82, 83 have output the same signal value and, thus, no ringing could be detected. In one example, the ringing is considered to be acceptable when its amplitude is less than 10% of the difference between the high value and the low value of the output signal RX. In another example, the microcontroller 40 is configured to shift the sampling point to the left until a minimum sampling point value, wherein the minimum sampling point value depends on the characteristics of the low-pass filter 31 of the CAN receiver 30. This behavior is known to the microcontroller 40 and the microcontroller 40 may decide, based on the characteristics of the low-pass filter 31, where to shift the sampling point. As a result, a new sampling window for the microcontroller 40 can be evaluated. With this, a quicker and more reliable sampling can be achieved.

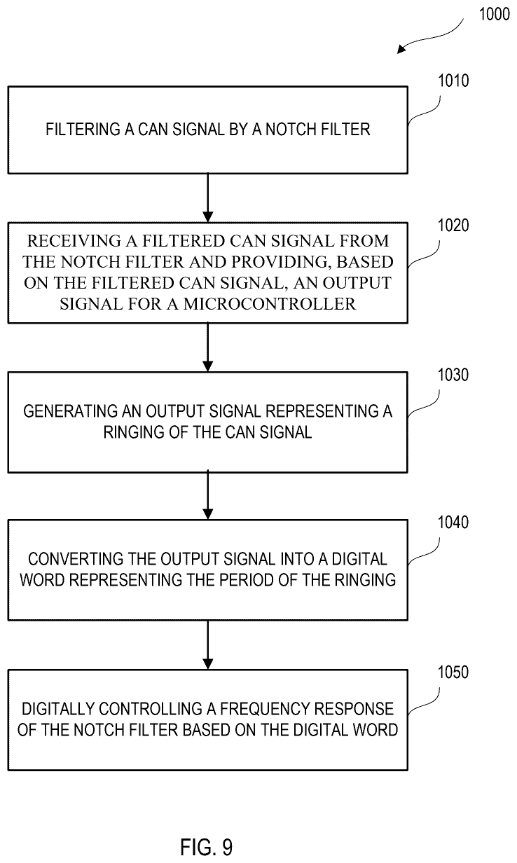

FIG. 9 is a flowchart illustrating an example method 1000 for removing the ringing from a CAN signal. The example process 1000 can be employed to operate devices illustrated in this disclosure, such as the circuits according to FIGS. 1, 2, 5 and 6.

Process 1000 includes filtering, by an adaptive notch filter 10, a CAN signal CANH, CANL received from a CAN bus line L (step 1010). The notch filter 10 is configured to adaptively remove a ringing from the CAN signal. The adaptive notch filter 10 is arranged in front of a CAN receiver 30.

The process 1000 further comprises receiving, by the CAN receiver 30, a filtered CAN signal CANH′, CANL′ from the adaptive notch filter 10 and providing, based on the filtered CAN signal CANH′, CANL′, an output signal RX for a microcontroller 40 (step 1020). In one example, the filtered CAN signal CANH′, CANL′ from the adaptive notch filter 10 is further filtered by a low-pass filter 31 of the CAN receiver 30, so as to cut off the high frequencies of the filtered CAN signal.

The process 1000 also comprises generating, by a first comparator circuit 50, an output signal S_{RING} representing a ringing of the CAN signal CANH, CANL (step 1030). The first comparator circuit 50 is part of an adaptation loop 20 that also comprises a time-to-digital converter 6 and a digital control circuit 70 and that is connected to the CAN bus line L. The adaptation loop 20 determines a frequency or a period of the ringing and controls a frequency response of the adaptive notch filter 10. The first comparator circuit 50 compares the CAN signal CANH, CANL to a predetermined threshold. The output signal S_{RING} is a square-wave signal. In one example, the first comparator circuit 50 comprises a hysteresis comparator with a threshold of 0V and the output signal S_{RING} has a high value when the CAN signal has a positive amplitude. In one example, the CAN signal CANH, CANL is filtered by a high-pass filter 90 before being input into the first comparator circuit 50. With this, the DC components of the CAN signal can be removed and the signal input to the first comparator circuit 50 essentially comprises the ringing. The output signal S_{RING} thus only contains high value sections when there is ringing. The width of the high value sections corresponds to a half-period of the ringing.

The process 1000 further comprises converting, by the time-to-digital converter 60, the output signal S_{RING} of the first comparator circuit 50 into a digital word T_{RING} (a bit string) representing a frequency of the ringing (step 1040). In one example, the time-to-digital converter 60 is a high resolution TDC with a resolution of 100 ps. This corresponds to a sampling frequency of 100 GHz and makes it possible to obtain a precise sampling of the output signal S_{RING} representing the ringing, since the ringing frequency is typically between 10 and 40 MHz.

In addition, the process 1000 comprises digitally controlling, by the digital control circuit 70, a frequency response of the adaptive notch filter 10 based on the digital word T_{RING} (step 1050). In one example, the notch filter 10 comprises at least one array of capacitors, wherein the capacitors can be respectively switched by a corresponding switch and wherein a notch frequency fₙ and a quality factor Q of the notch filter 10 depend on the capacity of the array of capacitors. The digital control circuit 70 outputs a digital control signal CTL that controls the switching of the capacitors and is, thus, able to shift the notch frequency. In one example, the digital control circuit 70 controls the notch filter 10 such that the notch frequency fₙ is equal to the ringing frequency. In one example, the digital control circuit 70 controls other parameters of the frequency response of the notch filter 10, such as the quality factor Q, the stop frequency bandwidth Δf and the cut-off frequencies at 3 dB f₁ and f₂. The adaptation may be achieved in various iterations. If the first comparator circuit 50 does not detect any ringing (i.e. when the output signal S_{RING} does not contain any high value portions), the digital control circuit keeps sending the same control signal and the notch filter 10 is not adapted. In one example, a cut-off frequency f_{LP} of the low-pass filter 31 is shifted based on the frequency response of the notch filter 10, in particular based on the notch frequency fₙ of the notch filter 10.

In one example, the process 1000 further comprises sampling, by the microcontroller 40, the output signal RX of the CAN receiver 30. The output signal RX is a square-wave signal that corresponds to the differential CAN signal after filtering by the notch filter 10 and by the low-pass filter 31 of the CAN receiver 30. In one example, before the adaptation of the notch filter 10, the output signal RX is sampled at a sampling point SP that is located at the end of a bit period of the RX signal, for example at 90% of the length of the bit period. This is to prevent the sampling from being affected by the ringing.

The process 1000 also comprises receiving, by a second comparator circuit 80, as inputs, the filtered CAN signal CANH′, CANL′ after filtering by the notch filter 10. In one example, the second comparator circuit 80 determines whether an amplitude of the ringing of the filtered CAN signal CANH′, CANL′ is less than a predetermined threshold. The second comparator circuit 80 outputs a corresponding output signal CS to the microcontroller that indicates whether the ringing is acceptable, i.e. whether it is kept under an acceptable threshold.

The process 1000 further comprises adjusting, by the microcontroller 40, for each received bit, a sampling time window based on the output signal of the second comparator circuit 80. In one example, when the output signal CS indicates that the ringing is under the predetermined threshold, the sampling point SP is shifted towards the beginning of the bit period of the RX signal, for example at 10% of the length of the bit period. This is possible because the ringing is considered to be sufficiently low not to affect the sampling.

The present application describes a circuit configured to adaptively remove a ringing of a CAN signal in front of a CAN receiver. The circuit comprises an adaptive notch filter and an adaptation loop that is configured to determine a frequency of the ringing and to tune a frequency response, in particular a notch frequency and a quality factor, of the adaptive notch filter according to the determined ringing frequency. A bandwidth of a low-pass filter of the CAN signal may also be adapted depending on the determined ringing frequency or depending on the frequency response of the notch filter. The notch frequency and the quality factor of the notch filter, as well as the bandwidth of the low-pass filter, may be adapted in various iterations to achieve a more accurate tuning. When the adaptation loop no longer detects the ringing, the adaptation can be stopped. The adaptation loop may comprise a time-to-digital converter with a high resolution and may complete an adaptation round of the notch filter within one period of the ringing. The notch filter may be digitally controlled by a digital control circuit and have a very simple design. An additional comparator circuit may also be implemented to check whether the adaptation reached a target cancellation of the ringing and may send a corresponding information to a microcontroller, which may then evaluate whether to extend a sampling window for sampling an output signal of the CAN receiver. With this, it is possible to sample the output signal of the receiver faster and more accurately. The circuit according to the present application makes it possible to quickly and efficiently remove the ringing on the CAN bus, wherein the design of the circuit remains particularly simple. In particular, the proposed circuit is independent from the CAN bus characteristics and the network topology. By removing the ringing of the CAN bus, the data rate on the bus can be increased and a reliable CAN bus communication can be ensured, even at high frequencies.

Although various embodiments have been illustrated and described with respect to one or more specific implementations, alterations and/or modifications may be made to the illustrated examples without departing from the spirit and scope of the features and structures recited herein. With particular regard to the various functions performed by the above described components or structures (units, assemblies, devices, circuits, systems, etc.), the terms (including a reference to a “means”) used to describe such components are intended to correspond—unless otherwise indicated—to any component or structure that performs the specified function of the described component (e.g., that is functionally equivalent), even if it is not structurally equivalent to the disclosed structure that performs the function in the herein illustrated exemplary implementations of the present disclosure.

Although the present disclosure is not so limited, the following numbered examples demonstrate one or more aspects of the disclosure.
Example 1. A circuit comprising: a CAN bus line (L) that comprises two wires; an adaptive notch filter (10) coupled to the CAN bus line (L) and configured to filter a CAN signal (CANH, CANL) received from the CAN bus line (L); a CAN receiver (30) configured to receive a filtered CAN signal (CANH′, CANL′) from the adaptive notch filter (10) and to provide, based on the filtered CAN signal (CANH′, CANL′), an output signal (RX) for a microcontroller (40); a first comparator circuit (50) coupled to the CAN bus line (L) and configured to generate an output signal (SRING) representing a ringing of the CAN signal (CANH, CANL); a time-to-digital converter (60) coupled to the first comparator circuit (50) and configured to convert the output signal (SRING) of the first comparator circuit (50) into a digital word (TRING) representing a frequency of the ringing; and a digital control circuit (70) connected to the time-to-digital converter (60) and configured to digitally control a frequency response of the adaptive notch filter (10) based on the digital word (TRING).
Example 2. The circuit according to example 1, wherein the time-to-digital converter (60) is a ring-oscillator-based time-to-digital converter.
Example 3. The circuit according to example 1 or 2, wherein a resolution of the time-to-digital converter (60) is less than 200 ps, preferably less than 100 ps.
Example 4. The circuit according to any one of examples 1 to 3, wherein the frequency response of the adaptive notch filter (10) is determined by at least one of the following filter parameters: a notch frequency; a quality factor; a cut-off frequency; and a blocking frequency bandwidth.
Example 5. The circuit according to any one of examples 1 to 4, wherein the adaptive notch filter (10) is a second-order notch filter.
Example 6. The circuit according to any one of examples 1 to 5, wherein the adaptive notch filter (10) comprises at least one array of capacitors that are arranged in parallel and that are selectively switchable by corresponding switches, wherein the switches are configured to be switched on and off depending on a digital control signal (CTL) generated by the digital control circuit (70) based on the digital word (TRING).
Example 7. The circuit according to any one of claims 1 to 6, wherein the adaptive notch filter (10) comprises a voltage resistive divider, wherein the voltage resistive divider comprises at least one array of resistors that are arranged in parallel and that are selectively switchable by corresponding switches, wherein the switches are configured to be switched on and off depending on a digital control signal (CTL) generated by the digital control circuit (70) based on the digital word (TRING).
Example 8. The circuit according to any one of examples 1 to 7, wherein a delay of a loop, which comprises the first comparator circuit (50), the time-to-digital converter (60), the digital control circuit (70) and the adaptive notch filter (10), is less than 100 ns, preferably less than 80 ns, preferably less than 60 ns.
Example 9. The circuit according to any one of examples 1 to 8, wherein the frequency response of the adaptive notch filter (10) is adjusted within one period of the ringing.
Example 10. The circuit according to any one of examples 1 to 9, wherein the frequency response of the adaptive notch filter (10) is adjusted in multiple iterations.
Example 11. The circuit according to any one of examples 1 to 10, wherein the digital control circuit (70) is configured not to adjust the frequency response of the adaptive notch filter (10) if the first comparator circuit (50) does not detect any ringing.
Example 12. The circuit according to any one of examples 1 to 11, further comprising the microcontroller (40), wherein the microcontroller (40) is coupled to the CAN receiver (30) and is configured to sample the output signal (RX) of the CAN receiver (30); and a second comparator circuit (80) that is connected to the CAN bus line (L) and that is configured to receive, as inputs, the filtered CAN signal (CANH′, CANL′), wherein the microcontroller (40) is configured to adjust, for each received bit, a sampling time window based on an output signal of the second comparator circuit (80).
Example 13. The circuit according to example 12, wherein the microcontroller (40) is configured to adjust, for each received bit, the sampling time window when an amplitude of the ringing is less than a predetermined threshold of the second comparator circuit (80).
Example 14. The circuit according to any one of examples 1 to 13, wherein the CAN receiver (30) comprises a low-pass filter (31) that is configured to filter the filtered CAN signal, wherein a cut-off frequency of the low-pass filter (31) is adjustable based on the frequency response of the adaptive notch filter (10).
Example 15. A method, comprising: filtering, by an adaptive notch filter (10), a CAN signal (CANH, CANL) received from a CAN bus line (L); receiving, by a CAN receiver (30), a filtered CAN signal (CANH′, CANL′) from the adaptive notch filter (10) and providing, based on the filtered CAN signal (CANH′, CANL′), an output signal (RX) for a microcontroller (40); generating, by a first comparator circuit (50), an output signal (SRING) representing a ringing of the CAN signal (CANH, CANL); converting, by a time-to-digital converter (60), the output signal (SRING) of the first comparator circuit (50) into a digital word (TRING) representing a frequency of the ringing; and digitally controlling, by a digital control circuit (70), a frequency response of the adaptive notch filter (10) based on the digital word (TRING).
Example 16. The method of example 15, further comprising: sampling, by the microcontroller (40), the output signal (RX) of the CAN receiver (30); and receiving, by a second comparator circuit (80), as inputs, the filtered CAN signal (CANH′, CANL′); and adjusting, by the microcontroller (40), for each received bit, a sampling time window based on an output signal of the second comparator circuit (80).

1. A circuit comprising:
a CAN bus line (L) that comprises two wires;
an adaptive notch filter coupled to the CAN bus line (L) and configured to filter a CAN signal (CANH, CANL) received from the CAN bus line (L);
a CAN receiver configured to receive a filtered CAN signal (CANH′, CANL′) from the adaptive notch filter and to provide, based on the filtered CAN signal (CANH′, CANL′), an output signal (RX) for a microcontroller;
a first comparator circuit coupled to the CAN bus line (L) and configured to generate an output signal (S_{RING}) representing a ringing of the CAN signal (CANH, CANL);
a time-to-digital converter coupled to the first comparator circuit and configured to convert the output signal (S_{RING}) of the first comparator circuit into a digital word (T_{RING}) representing a frequency of the ringing; and
a digital control circuit connected to the time-to-digital converter and configured to digitally control a frequency response of the adaptive notch filter based on the digital word (T_{RING}).

2. The circuit of claim 1, wherein
the time-to-digital converter is a ring-oscillator-based time-to-digital converter.

3. The circuit of claim 1, wherein
a resolution of the time-to-digital converter is less than 200 ps, preferably less than 100 ps.

4. The circuit of claim 1, wherein
the frequency response of the adaptive notch filter is determined by at least one of the following filter parameters: a notch frequency; a quality factor; a cut-off frequency; and
a blocking frequency bandwidth.

5. The circuit of claim 1, wherein
the adaptive notch filter is a second-order notch filter.

6. The circuit of claim 1, wherein
the adaptive notch filter comprises at least one array of capacitors that are arranged in parallel and that are selectively switchable by corresponding switches, wherein the switches are configured to be switched on and off depending on a digital control signal (CTL) generated by the digital control circuit based on the digital word (T_{RING}).

7. The circuit of claim 1, wherein
the adaptive notch filter comprises a voltage resistive divider, wherein the voltage resistive divider comprises at least one array of resistors that are arranged in parallel and that are selectively switchable by corresponding switches, wherein the switches are configured to be switched on and off depending on a digital control signal (CTL) generated by the digital control circuit based on the digital word (T_{RING}).

8. The circuit of claim 1, wherein
a delay of a loop, which comprises the first comparator circuit, the time-to-digital converter, the digital control circuit and the adaptive notch filter, is less than 100 ns, preferably less than 80 ns, preferably less than 60 ns.

9. The circuit of claim 1, wherein
the frequency response of the adaptive notch filter is adjusted within one period of the ringing.

10. The circuit of claim 1, wherein
the frequency response of the adaptive notch filter is adjusted in multiple iterations.

11. The circuit of claim 1, wherein
the digital control circuit is configured not to adjust the frequency response of the adaptive notch filter if the first comparator circuit does not detect any ringing.

12. The circuit of claim 1, further comprising
the microcontroller, wherein the microcontroller is coupled to the CAN receiver and is configured to sample the output signal (RX) of the CAN receiver; and
a second comparator circuit that is connected to the CAN bus line (L) and that is configured to receive, as inputs, the filtered CAN signal (CANH′, CANL′),
wherein the microcontroller is configured to adjust, for each received bit, a sampling time window based on an output signal of the second comparator circuit.

13. The circuit according to claim 12, wherein
the microcontroller is configured to adjust, for each received bit, the sampling time window when an amplitude of the ringing is less than a predetermined threshold of the second comparator circuit.

14. The circuit of claim 1, wherein
the CAN receiver comprises a low-pass filter that is configured to filter the filtered CAN signal, wherein a cut-off frequency of the low-pass filter (31) is adjustable based on the frequency response of the adaptive notch filter.

15. A method, comprising:
filtering, by an adaptive notch filter, a CAN signal (CANH, CANL) received from a CAN bus line (L);
receiving, by a CAN receiver, a filtered CAN signal (CANH′, CANL′) from the adaptive notch filter and providing, based on the filtered CAN signal (CANH′, CANL′), an output signal (RX) for a microcontroller;
generating, by a first comparator circuit, an output signal (S_{RING}) representing a ringing of the CAN signal (CANH, CANL);
converting, by a time-to-digital converter, the output signal (S_{RING}) of the first comparator circuit into a digital word (T_{RING}) representing a frequency of the ringing; and
digitally controlling, by a digital control circuit, a frequency response of the adaptive notch filter based on the digital word (T_{RING}).

16. The method of claim 15, further comprising:
sampling, by the microcontroller, the output signal (RX) of the CAN receiver; and
receiving, by a second comparator circuit, as inputs, the filtered CAN signal (CANH′, CANL′); and
adjusting, by the microcontroller, for each received bit, a sampling time window based on an output signal of the second comparator circuit.
